(19) United States
(12) Patent Application Publication
(10) Pub. No.: US 2003/0062571 A1
(43) Pub. Date: Apr. 3, 2003

(54) Low noise microwave transistor based on low carrier velocity dispersion control

(76) Inventor: Luiz M. Franca-Neto, Hillsboro, OR (US)

Correspondence Address: Seth Z. Kalson, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/971,271

(22) Filed: Oct. 3, 2001

(51) Int. Cl. H01L 29/76

(52) U.S. Cl. 257/335

(57) ABSTRACT

A low noise microwave MOSFET fabricated with source-side halo implantation. The dopant concentration has an asymmetrical horizontal profile along the channel from the source to the drain.

### FIELD

Embodiments of the present invention relate to transistors, and more particularly, to low noise microwave transistors.

### BACKGROUND

In many communication systems, low noise receivers are used to detect low power signals. A high-level functional diagram of a communication receiver is shown in FIG. 1. LNA (Low Noise Amplifier) 102 amplifiers a signal received by antenna 104. Mixer 108 mixes a sinusoidal signal from LOC (Local Oscillator) 106 with the output signal of LNA 102, and the result is low pass filtered by LPF (Low Pass Filter) 110. LPF 110 may shift the received signal to an intermediate frequency, or perhaps to baseband. The output of LNA 102 is mixed with quadrature signals to provide inphase and quadrature components, and these quadrature components are sampled and quantized by A/D (Analog-to-Digital Converter) 112 and A/D 114, where the digital quadrature data is provided to detector 116. Detector 116 may perform matched filtering, including convolutional decoding, to provide estimates of the transmitted digital data. Depending upon the carrier frequency of the transmitted signal, some or all of the mixing and lowpass filtering in FIG. 1 may be performed in the digital domain.

Every component in a communication receiver has the potential to add unwanted noise, so that the signal-to-noise ratio at the output port of a component may be larger than the signal-to-noise ratio at its input port. Low noise devices are used in a LNA so as to not substantially contribute to the noise power. By design, usually a LNA provides enough gain so that its noise-figure substantially defines the overall noise-figure of the receiver. Historically, CMOS (Complementary Metal Oxide Semiconductor) devices have not been used in the front end of a receiver, such as LNA 102, because they have not been fast enough to operate at radio or microwave frequencies, or they have not been particularly low noise devices. However, with recent scaling of CMOS technology to deep sub-micron device sizes, the use of CMOS receivers in the radio and microwave frequency range is becoming a practical possibility. Nevertheless, as CMOS technology scales to deep sub-micron device size, there is an increase in the magnitude of the electric field component along the direction of the channel. This increased electric field component causes an increase in source-to-drain current noise due to carrier heating. We will refer to the component of an electric field along the channel direction as the “horizontal” component.

MOSFETs (Metal Oxide Semiconductor Field Effect Transistor) having asymmetric channels are known to provide high speed switching. An asymmetric channel may be realized by single-sided halo implantation. For example, referring to a simplified cross-sectional view of a MOSFET in FIG. 2 having source 202, drain 204, and gate 206, in source-side halo implanting dopants are implanted asymmetrically as indicated by the direction of the arrows. This results in a channel doping concentration gradient, with the doping concentration higher on the source side relative to the drain side. With source-side halo implantation, the horizontal electric field reaches a critical value closer to the source when compared to a uniformly doped channel, where the critical value is that value of the electric field for which the carrier mean velocity reaches its maximum (velocity saturation). With the carriers reaching their maximum mean velocity sooner, the switching speed and saturation source-to-drain current increases relative to the uniformly doped channel case.

The effective channel length is similar to the gate length when the asymmetric MOSFET is OFF, but when the asymmetric MOSFET is ON and has a low V_{DD}, the effective channel length is much shorter compared to a conventional symmetric channel MOSFET. See “Channel Engineering for High Speed Sub-1.0V Power Supply Deep Sub-micron CMOS,” by Cheng et al., 1999 Symposium on VLSI Technology Digest of Technical Papers, pp. 69-70. It has been reported that an asymmetric channel MOSFET may be suitable for low noise applications because of its short effective channel length. See “Silicon RF-GCMOS IC Technology for RF Mixed-Mode Wireless Applications,” by Jun Ma et al., Microwave Symposium Digest, 1997, IEEE MTT-S International, Vol. 1, 1997, pp. 123-127.

### BRIEF DESCRIPTION OF THE DRAWINGS

FIG. 1 provides a system level diagram of a communication receiver.

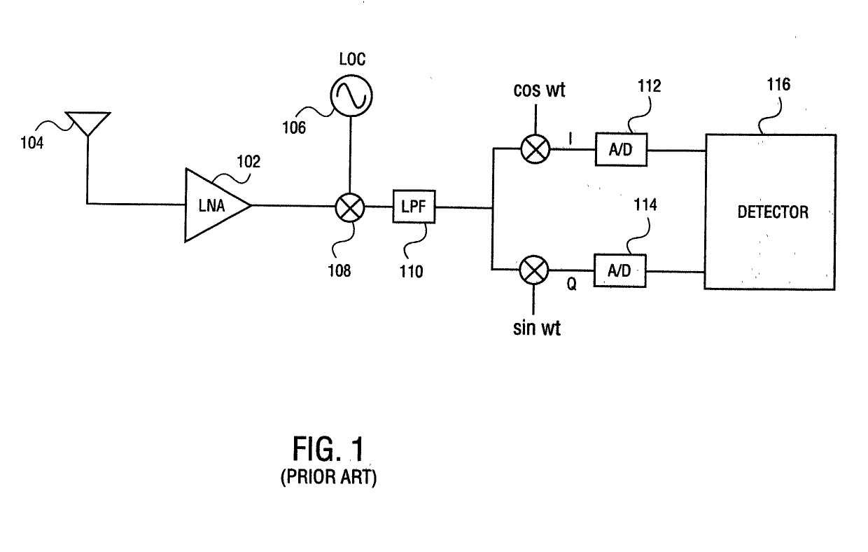

FIG. 2 illustrates source-side halo implantation.

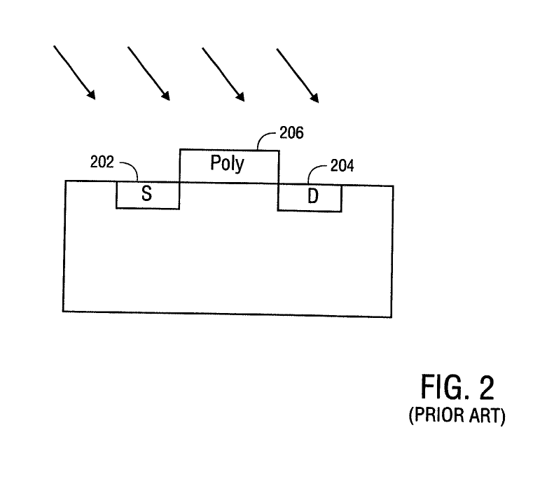

FIG. 3 illustrates horizontal electric field intensity for a MOSFET channel according to an embodiment of the present invention.

FIG. 4 is a high-level circuit diagram for a power amplifier according to an embodiment of the present invention.

### DESCRIPTION OF EMBODIMENTS

The low noise property of asymmetric channel MOSFETs is not based upon its short effective channel length, as discussed in some prior art, but is based upon the profile of the carrier concentration within the channel. As discussed below, the carrier concentration profile affects the horizontal electric field within the device channel, which in turn affects the variance of the carrier mean velocity and consequently the intrinsic noise power of the device.

Thermal noise in a slab of nondegenerate semiconductor material of small transversal area and thickness may be related to the distribution of carrier velocities by the expression:

$$\frac{⟨ {i}^{2} ⟩}{{I}^{2}} = \frac{{σ}^{2}}{{v}_{m}^{2}} , \qquad ( 1 )$$

where <i²> is the total current noise power (an integration of the noise power spectrum over all frequencies), I is the DC current through the semiconductor slab, σ² is the variance of the carrier velocity distribution, and νₘ is the mean velocity of the carrier ensemble. The overall electrical behavior and noise performance of a MOSFET for any bias may be calculated by representing the MOSFET channel as a series of semiconductor slabs, with perhaps varying current noise power for the semiconductor slabs, governed by equation (1).

As device channel length is decreased for a given source-to-drain voltage, the magnitude of the maximum horizontal electric field in the device channel is increased. This leads to an increase in the variance of the carrier velocity, and from equation (1) it follows that the noise power is increased. Consequently, as process technology allows for smaller device size, the noise power may be adversely affected.

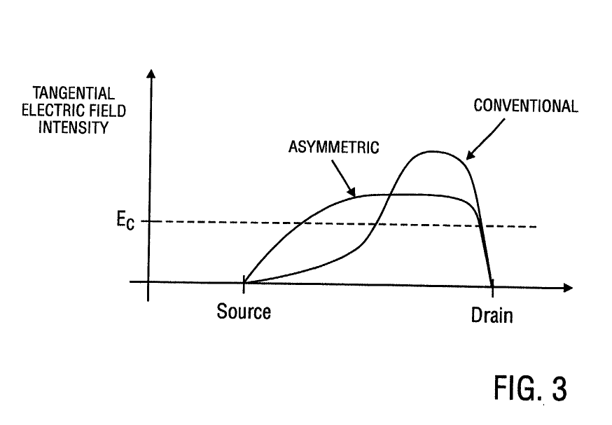

An approach for reducing the carrier velocity variance is to vary the carrier concentration profile from source to drain. The carrier concentration profile is such that there is a greater dopant concentration on the source side than the drain side, which may be realized by source-side halo implantation. FIG. 3 depicts the horizontal electric field intensity from source to drain in a conventional MOSFET (e.g., where the channel is doped by double-side halo implantation) and in a low noise asymmetric channel MOSFET in which source-side halo implantation has been used. In FIG. 3, the horizontal electric filed component is indicated by the y-axis and the channel dimension is indicated by the x-axis, where the critical electric field intensity is denoted by E_{C}.

As observed from FIG. 3, the critical electric field intensity for the source-side halo implanted MOSFET occurs closer to the source side than for the case of the conventional MOSFET, so that the carriers travel over a longer portion of the channel at their maximum mean velocity for the source-side halo implanted MOSFET than for the case of the conventional MOSFET. This results in faster switching. Furthermore, note that the maximum electric field intensity is smaller for the source-side halo implanted MOSFET, which contributes not only to the speed of the device, but also contributes to a lower intrinsic noise power than for the conventional MOSFET case.

In an embodiment of the present invention, source-side halo implantation is used to achieve a carrier concentration profile so that the gradient of the horizontal electric field intensity is substantially small, relative to the conventional MOSFET, over a substantial portion of the channel. For example, for the simplified one-dimensional case in FIG. 3, the gradients are equivalent to the slope of the curves, and it is seen that the slope of the curve for the source-side halo implanted MOSFET is smaller than that for the conventional MOSFET over most of the channel length. A relatively small gradient leads to smaller variance in carrier mean velocity, leading to smaller noise power. In addition, computer simulations on carrier velocity dispersion also indicate that at typical RF and microwave biases, the final carrier concentration profile along a channel with graded doping, such as the channel of a single-side halo transistor, more effectively contributes to diminishing the carrier dispersion produced by the horizontal electric than in the conventional transistor case. See “Noise in High Electric Field Transport and Low Noise Field Effect Transistor Design: The Ergodic Method,” by Franca-Neto, L. M., Ph.D. dissertation, Stanford University, May 1999.

For some embodiment MOSFETs, the dopant implantation is such that no part of the channel is ON when the gate-to-source voltage is zero. That is, the horizontal dopant concentration profile is such that the channel does not undergo inversion when the gate-to-source voltage is zero.

Because source-sided halo implantation provides for substantially small dopant implantation on the drain side, the junction capacitance at the drain side is reduced, and thereby the maximum operation frequency reachable by a source-side halo implanted MOSFET is increased relative to a conventional MOSFET. Furthermore, because the maximum of the horizontal electric field intensity is reduced with source-side halo implantation, an asymmetric channel MOSFET may be able to withstand a higher voltage without breakdown than a convention MOSFET. These features indicate that a source-side halo implanted MOSFET may be useful in power amplifiers, and in particular, microwave power amplifiers because of the reduced drain capacitance.

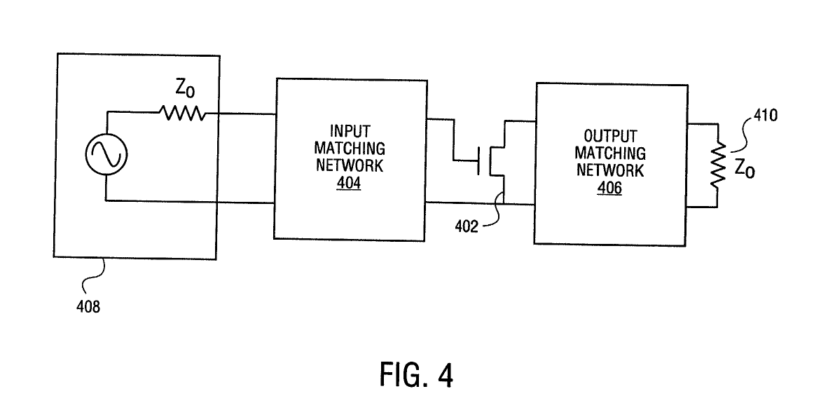

A basic, high-level circuit configuration for a MOSFET power amplifier is shown in FIG. 4, comprising nMOSFET 402, input matching network 404, and output matching network 406. Signal source 408 provides an input signal to input matching network 404 and may comprise a modulator, where some portions of the modulation may be performed in the digital domain. Output load 410 may be an antenna. With nMOSFET 402 fabricated using source-side halo implanted, the power amplifier of FIG. 4 is expected to operate at a higher frequency and at a higher voltage than for the case of a conventionally doped MOSFET.

Various modifications may be made to the disclosed embodiments without departing from the scope of the invention as claimed below.

What is claimed is:

1. A method of fabricating a MOSFET having a channel, a source, and a drain, the method comprising:
implanting dopants in the channel from the source to the drain to provide an asymmetric horizontal dopant concentration profile with higher concentration near the source than the drain;
wherein the dopant concentration is such that when the MOSFET is ON, a horizontal electric field intensity in the channel has a gradient substantially small over a substantial portion of the channel.

2. The method as set forth in claim 1, wherein the implantation is performed by source-side halo implantation.

3. A method of fabricating a MOSFET having a channel, a source, and a drain, the method comprising:
implanting dopants in the channel from the source to the drain to provide an asymmetric horizontal dopant concentration profile with higher concentration near the source than the drain;
wherein the dopant concentration is such that when the MOSFET is ON, a horizontal electric field intensity in the channel has a gradient in the channel direction substantially less along a substantial portion of the channel than if the dopants were implanted uniformly from the source to the drain.

4. The method as set forth in claim 3, wherein the implantation is performed by source-side halo implantation.

5. A MOSFET comprising:
a source;
a drain; and
a channel having an asymmetrical horizontal dopant concentration profile from the source to the drain such that when the MOSFET is ON, a horizontal electric field intensity in the channel has a gradient substantially small over a substantial portion of the channel.

6. A MOSFET comprising:
a source;
a drain; and
a channel having an asymmetrical horizontal dopant concentration profile from the source to the drain such that when the MOSFET is ON, a horizontal electric field intensity in the channel has a gradient in the channel direction substantially less along a substantial portion of the channel than if the dopants were implanted uniformly from the source to the drain.

7. A receiver comprising:
an antenna; and
a amplifier coupled to the antenna, the amplifier comprising a MOSFET, the MOSFET comprising:
a source;
a drain; and
a channel having an asymmetrical horizontal dopant concentration profile from the source to the drain such that when the MOSFET is ON, a horizontal electric field intensity in the channel has a gradient substantially small over a substantial portion of the channel.

8. A receiver comprising:
an antenna; and
a amplifier coupled to the antenna, the amplifier comprising a MOSFET, the MOSFET comprising:
a source;
a drain; and
a channel having an asymmetrical horizontal dopant concentration profile from the source to the drain such that when the MOSFET is ON, a horizontal electric field intensity in the channel has a gradient in the channel direction substantially less along a substantial portion of the channel than if the dopants were implanted uniformly from the source to the drain.

9. A power amplifier comprising:
a MOSFET having a source, a drain, and a channel; and
an output matching network coupled to the drain and the source of the MOSFET;
wherein the channel has an asymmetrical horizontal dopant concentration profile from the source to the drain such that when the MOSFET is ON, a horizontal electric field intensity in the channel has a gradient substantially small over a substantial portion of the channel.

10. A power amplifier comprising:
a MOSFET having a source, a drain, and a channel; and
an output matching network coupled to the drain and the source of the MOSFET;
wherein the channel has an asymmetrical horizontal dopant concentration profile from the source to the drain such that when the MOSFET is ON, a horizontal electric field intensity in the channel has a gradient in the channel direction substantially less along a substantial portion of the channel than if the dopants were implanted uniformly from the source to the drain.

11. A transceiver comprising a power amplifier, the power amplifier comprising:
a MOSFET having a source, a drain, and a channel; and
an output matching network coupled to the drain and the source of the MOSFET;
wherein the channel has an asymmetrical horizontal dopant concentration profile from the source to the drain such that when the MOSFET is ON, a horizontal electric field intensity in the channel has a gradient substantially small over a substantial portion of the channel.

12. A transceiver comprising a power amplifier, the power amplifier comprising:
a MOSFET having a source, a drain, and a channel; and
an output matching network coupled to the drain and the source of the MOSFET;
wherein the channel has an asymmetrical horizontal dopant concentration profile from the source to the drain such that when the MOSFET is ON, a horizontal electric field intensity in the channel has a gradient in the channel direction substantially less along a substantial portion of the channel than if the dopants were implanted uniformly for the source and drain.

13. A MOSFET comprising:
a source;
a drain;
a gate, the gate and source having a gate-to-source voltage; and
a channel having an asymmetrical horizontal dopant concentration profile from the source to the drain such that when the gate-to-source voltage is zero, no part of the channel is ON.
